(19) United States
(12) Patent Application Publication
(10) Pub. No.: US 2025/0287645 A1
(43) Pub. Date: Sep. 11, 2025

(54) FORK SHEET TRANSISTOR WITH VIA-TO-BACKSIDE POWER RAIL STRUCTURE

(71) Applicant: International Business Machines Corporation, Armonk, NY (US)

(72) Inventors: HUIMEI ZHOU, Albany, NY (US); Ruilong Xie, Niskayuna, NY (US); Nicolas Jean Loubet, GUILDERLAND, NY (US)

(21) Appl. No.: 18/598,668

(22) Filed: Mar. 7, 2024

(51) Int. Cl. H01L 29/423; H01L 21/8234; H01L 23/528; H01L 27/088; H01L 29/06; H01L 29/08; H01L 29/66; H01L 29/775; H01L 29/786

(52) U.S. Cl. CPC H10D 30/6735; H01L 23/5286; H10D 30/014; H10D 30/43; H10D 30/6757; H10D 62/121; H10D 62/151; H10D 64/017; H10D 84/0149; H10D 84/038; H10D 84/83

(57) ABSTRACT

A fork sheet transistor including a via-to-backside power rail (VBPR) structure electrically connecting a backside power rail to a source/drain region of a fork sheet transistor is provided. The fork sheet transistor can be integrated with a nanosheet transistor that also includes a VBPR structure electrically connecting a backside power rail to a non-active device area of the nanosheet transistor of the nanosheet transistor.

### BACKGROUND

The present application relates to semiconductor technology, and more particularly to a semiconductor structure including a via-to-backside power rail (VBPR) structure for electrically connecting a backside power rail to a source/drain region of a fork sheet transistor.

When forming a semiconductor structure including a plurality of complementary metal oxide semiconductor (CMOS) devices, such as integrated circuits, standard cells can be used as a base unit for designing and manufacturing the integrated circuits. The standard cell(s) can be used to form one or more functional circuits, and each standard cell can have the same footprint. Using standard cells when designing complex circuits and components reduces design and manufacture costs.

In use, each standard cell of a semiconductor structure requires power input (Vdd) and ground (Vss) connections. To power the various components thereof, each standard cell is generally coupled to a backside power rail which is electrically connected to an active layer of the standard cell to provide the power. In some instances, a plurality of backside power rails can be provided for each standard cell to respectively provide power and ground. Backside power rails are typically formed on the backside of a semiconductor substrate (or wafer). Such backside power rails are connected to a source/drain region of a field effect transistor (FET) utilizing a VBPR structure. Backside power rails are a promising solution for further semiconductor device scaling.

### SUMMARY

A fork sheet transistor including a VBPR structure electrically connecting a backside power rail to a source/drain region of a fork sheet transistor is provided. The fork sheet transistor can be integrated with a nanosheet transistor that also includes a VBPR structure electrically connecting a backside power rail to a source/drain region of the nanosheet transistor.

In one aspect of the present application, a semiconductor structure is provided. In one embodiment, the semiconductor structure includes a fork sheet transistor located on a frontside of a semiconductor device layer and including a plurality of semiconductor channel material nanosheets, a gate structure contacting each semiconductor channel material nanosheet of the plurality of semiconductor channel material nanosheets, and source/drain regions. The semiconductor structure further includes a backside power rail located on a backside of the semiconductor device layer, and a VBPR structure in electrical contact with the backside power rail and one of the source/drain regions of the fork sheet transistor. The semiconductor structure further includes a dielectric layer separating the VBPR structure from each of the gate structure, the plurality of semiconductor channel material nanosheets, the semiconductor device layer and the source/drain region that is in electrical contact with the backside power rail.

In another embodiment, the semiconductor structure includes a fork sheet transistor located on a frontside of a semiconductor device layer and including a plurality of semiconductor channel material nanosheets, a gate structure contacting each semiconductor channel material nanosheet of the plurality of semiconductor channel material nanosheets, and source/drain regions. The semiconductor structure further includes a backside power rail located on a backside of the semiconductor device layer, and a VBPR structure in electrical contact with the backside power rail and a topmost surface and a sidewall surface of one of the source/drain regions of the fork sheet transistor. The semiconductor structure of this embodiment also includes a dielectric layer separating the VBPR structure from each of the gate structure, and the plurality of semiconductor channel material nanosheets.

### BRIEF DESCRIPTION OF THE DRAWINGS

FIG. 1 is a top down view of a device layout that can be used in the present application for both a fork sheet transistor and a nanosheet transistor.

FIG. 2 is a cross sectional view of a first exemplary structure through cut A-A of FIG. 1 that can be employed in accordance with an embodiment of the present application, the first exemplary structure is used in providing a nanosheet transistor.

FIG. 3 is a cross sectional view of a second exemplary structure also through cut A-A of FIG. 1 that can be employed in accordance with an embodiment of the present application, the second exemplary structure is used in providing a fork sheet transistor.

FIG. 4A is a cross sectional view of the first exemplary structure shown in FIG. 2 after performing a replacement gate process.

FIG. 4B is a cross sectional view of the first exemplary structure shown in FIG. 4A and through cut B-B shown in FIG. 1.

FIG. 5A is a cross sectional view of the second exemplary structure shown in FIG. 3 after performing a replacement gate process.

FIG. 5B is a cross sectional view of the second exemplary structure shown in FIG. 5A and through cut B-B shown in FIG. 1.

FIGS. 6A-6B are cross sectional views of the first exemplary structure shown in FIGS. 4A-4B, respectively, after performing a gate cut process.

FIGS. 7A-7B are cross sectional views of the second exemplary structure shown in FIGS. 5A-5B, respectively, after performing the gate cut process to the first exemplary structure.

FIGS. 8A-8B are cross sectional views of the first exemplary structure shown in FIGS. 6A-6B, respectively, after performing a gate cut trench fill process.

FIGS. 9A-9B are cross sectional views of the second exemplary structure shown in FIGS. 7A-7B, respectively, after performing the gate cut trench fill process to the first exemplary structure.

FIGS. 10A-10B are cross sectional views of the first exemplary structure shown in FIGS. 8A-8B, respectively, after forming a first via opening.

FIGS. 11A-11B are cross sectional views of the second exemplary structure shown in FIGS. 9A-9B, respectively, after forming a second via opening.

FIGS. 12A-12B are cross sectional views of the first exemplary structure shown in FIGS. 10A-10B, respectively, after forming a frontside source/drain contact mask.

FIGS. 13A-13B are cross sectional views of the second exemplary structure shown in FIGS. 11A-11B, respectively, after forming the frontside source/drain contact mask.

FIGS. 14A-14B are cross sectional views of the first exemplary structure shown in FIGS. 12A-12B, respectively, after performing a frontside source/drain contact etch.

FIGS. 15A-15B are cross sectional views of the second exemplary structure shown in FIGS. 13A-13B, respectively, after performing the frontside source/drain contact etch.

FIG. 16 is a cross sectional view of the first exemplary structure shown in FIG. 14B after performing an optional etch.

FIG. 17 is a cross sectional view of the second exemplary structure shown in FIG. 15B after performing the optional etch.

FIGS. 18A-18B are cross sectional views of the first exemplary structure shown in FIGS. 14A-14B, respectively, after forming frontside contact structures including a VBPR structure.

FIGS. 19A-19B are cross sectional views of the second exemplary structure shown in FIGS. 15A-15B, respectively, after forming frontside contact structures including a VBPR structure.

FIGS. 20A-20B are cross sectional views of the first exemplary structure shown in FIGS. 18A-18B, respectively, after additional frontside processing and then performing backside processing.

FIGS. 21A-21B are cross sectional views of the second exemplary structure shown in FIGS. 19A-19B, respectively, after additional frontside processing and then performing backside processing.

FIGS. 22A-22B are cross sectional views of the first exemplary structure shown in FIGS. 20A-20B, respectively, after forming backside power rails to provide power to the nanosheet transistor.

FIGS. 23A-23B are cross sectional views of the second exemplary structure shown in FIGS. 21A-21B, respectively, after forming backside power rails to provide power to the fork sheet transistor.

FIG. 24 is a cross sectional view of an alternative fork sheet transistor that be formed in the second active device area.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Fork sheet transistors are a natural extension of vertically stacked gate-all-around (GAA) nanosheet transistors. Contrary to the GAA nanosheet transistor in the fork sheet transistor, the nanosheets are now controlled by a tri-gate forked structure, realized by introducing a dielectric pillar (i.e., dielectric wall) attached to at least one of vertical edges of the semiconductor channel material fork sheets. The dielectric pillar can be formed between pFET and nFET devices. The dielectric pillar physically isolates the pFET active device region from the nFET active device region, allowing a much tighter n-to-p spacing. Alternatively, the dielectric pillar can also be formed at cell boundaries (i.e., between pFET and pFET devices, or between nFET and nFET devices) allowing a much tighter p-to-p or n-to-n spacing. Because of this reduced n-to-p (or n-to-n, or p-to-p) separation, the fork sheet device has superior area and performance scalability as compared to nanosheet transistors.

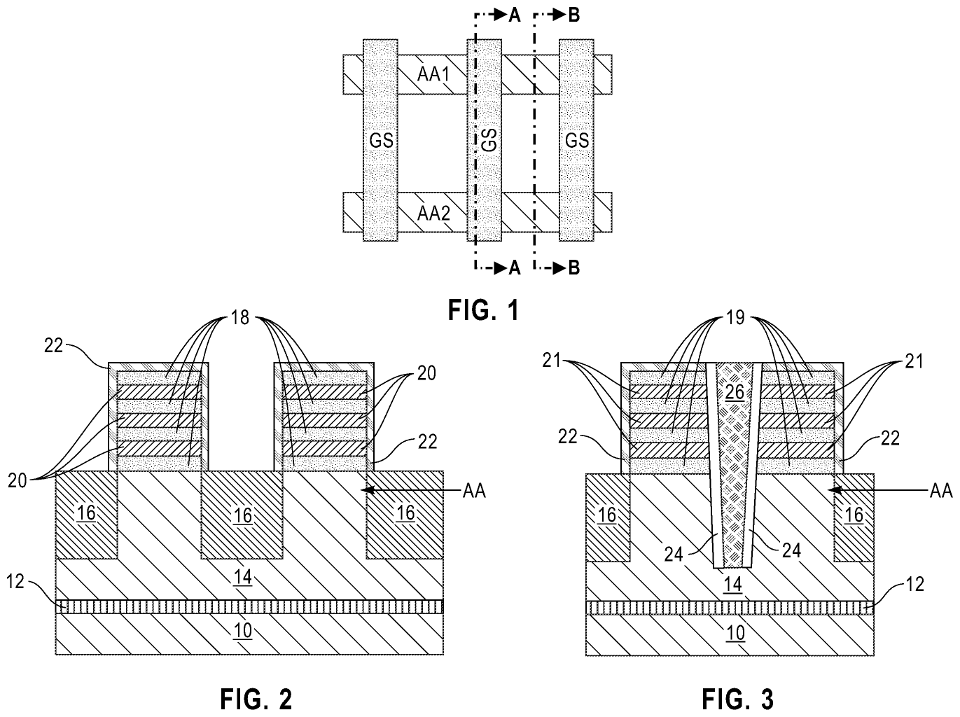

Referring first to FIG. 1, there is illustrated a device layout that can be used in the present application. The device layout illustrated in FIG. 1 includes a first active device area, AA1, and a second active device area, AA2. AA1 and AA2 are separated from each other by a non-active device area (not specifically labeled in FIG. 1) which can include a shallow trench isolation structure. The device layout illustrated in FIG. 1 also includes three gate structures, GS, which run parallel to each other, but perpendicular to AA1 and AA2. The device layout illustrated in FIG. 1 also includes cut A-A and cut B-B. Cut A-A extends from AA1 to AA2 and is through the middle gate structure. Cut B-B extends from AA1 to AA2 and is through a source/drain area to the right of the middle gate structure. In the present application, this device layout will be applied to both nanosheet transistors and fork sheet transistors. In some embodiments, the nanosheet transistors can be omitted, and only fork sheet transistors are formed.

The present application provides a fork sheet transistor including a VBPR structure that is present in a non-active device area and a source/drain area. In the source/drain region, the VBPR structure electrically connects a backside power rail to a source/drain region of the fork sheet transistor. The fork sheet transistor can be integrated with a nanosheet transistor that also includes a VBPR structure electrically connecting a backside power rail to one of the source/drain regions of the nanosheet transistor. In the present application, a dielectric layer separates the VBPR structure that is present in the nonactive device region from a gate structure and each of the semiconductor channel material nanosheet of the fork sheet transistor, a semiconductor device layer, and a backside interlayer dielectric layer. The dielectric layer extends from a topmost surface of the gate structure to a topmost surface of the buried power rail that is present in the backside interlayer dielectric layer; each of the semiconductor channel material nanosheet of the fork sheet transistor has an end that directly contacts the dielectric layer. In the source/drain area, the dielectric layer can be entirely present, partially present or not present at all. Thus, and in the source/drain area, the VBPR structure can be entirely isolated from the sidewalls of the source/drain region of the fork sheet transistor by the dielectric layer, or it can be in contact with the sidewalls of the source/drain region of the fork sheet transistor. These and other aspects of the present application will now be described in greater detail.

Referring now to FIG. 2, there is illustrated a first exemplary structure through cut A-A of FIG. 1 that can be employed in accordance with an embodiment of the present application. The first exemplary structure will be used in the present application in forming nanosheet transistors. In some embodiments, the first exemplary structure is omitted. The first exemplary structure illustrated in FIG. 2 includes at least one first material stack (two of which are illustrated in FIG. 2 by way of one example) of alternating first sacrificial semiconductor material nanosheets 18 and first semiconductor channel material nanosheets 20 located on an active device area, AA, of a substrate that includes the semiconductor device layer 14. The first semiconductor channel material nanosheets 20 will be used as a semiconductor channel material structure of a nanosheet transistor. In some embodiments, the substrate can also include, in addition to the semiconductor device layer 14, a semiconductor base layer 10, an etch stop layer 12 or a combination of the semiconductor base layer 10 and the etch stop layer 12. A shallow trench isolation structure 16 is located adjacent to each of the active device areas illustrated in FIG. 2 and between each of the first material stacks. The shallow trench isolation structures 16 are present in the nonactive device area mentioned above in regard to FIG. 1 As is shown, a sacrificial liner 22 is located on at least the sidewalls and a topmost surface of each of the first material stacks.

The semiconductor base layer 10 is composed of a first semiconductor material having semiconducting properties. Examples of first semiconductor materials that can be used to provide the semiconductor base layer 10 include, but are not limited to, silicon (Si), a silicon germanium (SiGe) alloy, a silicon germanium carbide (SiGeC) alloy, germanium (Ge), III/V compound semiconductors or II/VI compound semiconductors. The semiconductor device layer 14 is composed of a second semiconductor material. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first and second semiconductor materials mentioned above. In one example, the semiconductor base layer 10 is composed of silicon, the etch stop layer 12 is composed of silicon dioxide, and the semiconductor device layer 14 is composed of silicon. Such a substrate including silicon/silicon dioxide/silicon can be referred to as a silicon-on-insulator (SOI) substrate. In another example, the semiconductor base layer 10 is composed of silicon, the etch stop layer 12 is composed of silicon germanium, and the semiconductor device layer 14 is composed of silicon. Such a semiconductor substrate including silicon/silicon germanium/silicon can be referred to as a bulk semiconductor substrate. A bulk semiconductor substrate including only the semiconductor device layer 14 is contemplated in the present application.

Each first sacrificial semiconductor material nanosheet 18 is composed of a fourth semiconductor material. The fourth semiconductor material that provides each first sacrificial semiconductor material nanosheet 18 is compositionally different from at least the second semiconductor material that provides the semiconductor device layer 14. In one example, each of the first sacrificial semiconductor material nanosheets 18 is composed of a silicon germanium alloy.

Each first semiconductor channel material nanosheet 20 is composed of a fifth semiconductor material that is compositionally different from at least the fourth semiconductor material that provides the first sacrificial semiconductor material nanosheets 18. The fifth semiconductor material that provides each first semiconductor material nanosheet 20 can be compositionally the same as, or compositionally different from, the second semiconductor material that provides the semiconductor device layer 14. In some embodiments, the fifth semiconductor material that provides each first semiconductor channel material nanosheet 20 provides high channel mobility for nFET devices. In other embodiments, the fifth semiconductor material that provides each first semiconductor channel material nanosheet 20 provides high channel mobility for pFET devices. In one example, each first semiconductor material nanosheet 20 is composed of silicon.

In some embodiments and as is illustrated in FIG. 2, each first material stack can include ‘n+1’ first sacrificial semiconductor material nanosheets 18 and ‘n’ first semiconductor channel material nanosheets 20 wherein n is an integer starting from 1, typically n is 2 or greater. In the illustrated embodiment, each first semiconductor channel material nanosheet 20 is thus sandwiched between a bottom first sacrificial semiconductor material nanosheet and a top first sacrificial semiconductor material nanosheet.

The shallow trench isolation structure 16 can be composed of any trench dielectric material such as, for example, silicon oxide. In some embodiments, a trench dielectric liner material such as, for example, SiN can be present along a sidewall and a bottom wall of the trench dielectric material. In some embodiments, the shallow trench isolation structure 16 can have a topmost surface that is substantially coplanar with a topmost surface of the semiconductor device layer 14. In other embodiments, the shallow trench isolation structure 16 can have a topmost surface that is vertically offset (i.e., higher or lower) than a topmost surface of the semiconductor device layer 14.

The sacrificial liner 22 is composed of a sacrificial dielectric material that is typically compositionally different from the trench dielectric material that provides the shallow trench isolation structure 16. In one example, the sacrificial liner 22 can be composed of SiO₂. The sacrificial liner 22 is typically, but necessarily always, a conformal layer. The term “conformal” denotes that a layer has a same thickness as measured from a horizontal surface of another layer as a thickness as measured from a vertical surface of the another layer.

The first exemplary structure illustrated in FIG. 2 can be formed utilizing nanosheet processing techniques that are well known to those skilled in the art. In some embodiments, the first exemplary structure illustrated in FIG. 2 can be formed by deposition of blanket layers of the fourth semiconductor material and blanket layers of the fifth semiconductor layer. In the present application, the number of blanket layers of fourth semiconductor material can vary so as to produce a desired number of first sacrificial semiconductor material nanosheets 18 and the number of blanket layers of fifth semiconductor material can vary to produce a desired number of first semiconductor channel material nanosheets 20. The deposition of the blanket layers can include, but is not limited to, chemical vapor deposition (CVD), physical vapor deposition (PECVD), or epitaxial growth. The terms “epitaxial growth” or “epitaxially growing” means the growth of a second semiconductor material on a growth surface of a first semiconductor material, in which the second semiconductor material being grown has the same crystalline characteristics as the first semiconductor material. In an epitaxial deposition process, the chemical reactants provided by the source gases are controlled and the system parameters are set so that the depositing atoms arrive at the growth surface of the first semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking. Lithography and etching can then be used to pattern the blanket deposited layers to form at least one precursor first material stack.

Next, the shallow trench isolation structure 16 is formed utilizing techniques well known to those skilled in the art. After forming the shallow trench isolation structure 16 at least one least one sacrificial gate structure (not illustrated in FIG. 2) including a sacrificial gate dielectric and a sacrificial gate material can be formed by deposition, lithography and etching. The least one sacrificial gate structure is formed straddling (i.e., on top of and adjacent to sidewalls) over the least one precursor first material stack. An etch is then used to convert the least one precursor first material stack into at least one first material stack; this etch utilizes the sacrificial gate structure as an etch mask. At this point of the present application, each first sacrificial semiconductor material nanosheet 18 of the first material stacks can be recessed and inner spacers (not shown in the cross sectional view provided, the inner spacers would be formed into and out of the plane of the drawing sheet containing FIG. 2) can be formed adjacent to each recessed end of the first sacrificial semiconductor material nanosheets 18. The sacrificial liner 22 can be formed by a deposition process such as, for example, CVD, PECVD or ALD.

Referring now to FIG. 3, there is illustrated a second exemplary structure also through cut A-A of FIG. 1 that can be employed in accordance with an embodiment of the present application. The second exemplary structure will be used in the present application in forming fork sheet transistors. In some embodiments, the second exemplary structure is integrated on the same substrate as the first exemplary structure illustrated in FIG. 2. The second exemplary structure illustrated in FIG. 3 includes at least one second material stack (two of which are illustrated in FIG. 3 by way of one example) of alternating second sacrificial semiconductor material nanosheets 19 and second semiconductor channel material nanosheets 21 located on an active device area, AA, of a substrate that includes at least the semiconductor device layer 14. In some embodiments, the substrate can also include, in addition to the semiconductor device layer 14, semiconductor base layer 10, etch stop layer 12 or a combination of the semiconductor base layer 10 and the etch stop layer 12, each of which have been defined above. Shallow trench isolation structure 16, as defined above, is located adjacent to one side of each of the second material stacks illustrated in FIG. 3 and is present in the non-active device area as described above with respect to FIG. 1. The second exemplary structure also includes a dielectric pillar structure located between the two second material stacks illustrated in FIG. 3. In the present application, the dielectric pillar structure is a bilayer structure including a sacrificial dielectric core 26 bounded on edge side by a dielectric layer 24. In the present application, one of the edges of each of the second semiconductor channel material nanosheets 21 is in direct contact with the dielectric layer 24. As is shown, sacrificial liner 22 (as defined above) is located on a sidewall and a topmost surface of each of the second material stacks.

Each second sacrificial semiconductor material nanosheet 19 is composed of a sixth semiconductor material. The sixth semiconductor material that provides each second sacrificial semiconductor material nanosheet 18 is compositionally different from at least the second semiconductor material that provides the semiconductor device layer 14. In one example, each second sacrificial semiconductor material nanosheet 19 is composed of a silicon germanium alloy. It is noted that in embodiments of the present application the sixth semiconductor material that provides each second sacrificial semiconductor material nanosheet 19 can be compositionally the same as, or compositionally different from, the fourth semiconductor material that provides the first sacrificial semiconductor material nanosheets 18.

Each second semiconductor channel material nanosheet 21 is composed of a seventh semiconductor material that is compositionally different from at least the sixth semiconductor material that provides the second sacrificial semiconductor material nanosheets 19. The seventh semiconductor material that provides each second semiconductor material nanosheet 21 can be compositionally the same as, or compositionally different from, the second semiconductor material that provides the semiconductor device layer 14. In some embodiments, the seventh semiconductor material that provides each second semiconductor channel material nanosheet 21 provides high channel mobility for nFET devices. In other embodiments, the seventh semiconductor material that provides each second semiconductor channel material nanosheet 21 provides high channel mobility for pFET devices. In one example, each second semiconductor material nanosheet 21 is composed of silicon.

In some embodiments and as is illustrated in FIG. 2, each second material stack can include ‘m+1’ second sacrificial semiconductor material nanosheets 19 and ‘m’ second semiconductor channel material nanosheets 21 wherein m is an integer starting from 1, typically m is 2 or greater. While not a requirement of the present application, m is generally equal to n so as to avoid topography issues. In the illustrated embodiment, each second semiconductor channel material nanosheet 21 is thus sandwiched between a bottom second sacrificial semiconductor material nanosheet and a top second sacrificial semiconductor material nanosheet.

The dielectric layer 24 of the dielectric pillar structure is composed of a first dielectric material, while the sacrificial dielectric core 26 of the dielectric pillar structure is composed of a second dielectric material that is compositionally different from the first dielectric material. In the present application, the first dielectric material and/or the second dielectric material are typically compositionally different from the sacrificial liner 22. In one example, the second dielectric material that provides the sacrificial dielectric core 26 is composed of silicon dioxide, while the second dielectric material that provides each dielectric layer 24 is composed of silicon nitride. Other second dielectric materials include, but are not limited to, a silicon carbon based dielectric such as, for example, silicon carbide or a dielectric including atoms of Si, C and O. Other first dielectric materials can also be used as long as there is a sufficient etch selectivity between the first and second dielectric materials so that the second dielectric material can be selectively removed relative to the first dielectric material.

The second exemplary structure illustrated in FIG. 3 can be formed utilizing fork sheet processing techniques that are well known to those skilled in the art. In embodiments of the present application, the second exemplary structure illustrated in FIG. 3 can be formed by deposition of blanket layers of the sixth semiconductor material and blanket layers of the seventh semiconductor layer. In the present application, the number of blanket layers of sixth semiconductor material can vary so as to produce a desired number of second sacrificial semiconductor material nanosheets 19 and the number of blanket layers of seventh semiconductor material can vary to produce a desired number of second semiconductor channel material nanosheets 21. The deposition of the blanket layers can include CVD, PECVD or epitaxial growth. Lithography and etching can then be used to pattern the blanket deposited layers to form at least one precursor second material stack. Shallow trench isolation structure 16 is then formed, followed by the sacrificial liner 22. Next, the dielectric pillar structure is formed by forming a dielectric pillar structure trench into the at least one precursor second material stack. A portion of the least one precursor second material stack remains on each side of the dielectric pillar structure trench. Each remaining portion can be referred to herein as a second material stack having a first length. The dielectric pillar structure trench extends into the semiconductor device layer 14. The dielectric pillar structure trench can be formed by lithography and etching. A layer of the first dielectric material described above is then formed lining the sidewalls and a bottom of the dielectric pillar structure trench and thereafter a directional etch is used to remove the second dielectric material from the bottom wall of the dielectric pillar structure trench to provide dielectric layer 24. A layer of the second dielectric material described above is them formed, and thereafter a planarization process such as, for example, chemical mechanical polishing (CMP) can be used to form the sacrificial dielectric core 26 of the dielectric pillar structure.

At this point of the processing, a sacrificial gate structure is formed over each of the second material stacks having the first length, and a nanosheet recess etch is used to convert the first length of each second material stack into a second length that is less than the first (this step is not illustrated in the cross sectional shown). Each second sacrificial semiconductor material nanosheet 19 of the second material stack can be recessed and inner spacers (not shown in the cross sectional view provided, the inner spacers would be formed into and out of the plane of the drawing sheet containing FIG. 3) can be formed adjacent to each end of the second sacrificial semiconductor material nanosheets 18. The sacrificial gate structure can then be removed from the structure.

In embodiments in which the first exemplary structure illustrated in FIG. 2 is integrated with the second exemplary structure illustrated in FIG. 3, the method can include forming the first and second precursor material stacks as described above. In such an embodiment, the precursor second material stack is formed to have a longer width than the first precursor material stack. Block mask technology can then be used protecting the first precursor material stack(s) or the second precursor material stack(s). The region not including the block mask can be processed to convert the respective percussor material stack into the first material stack or second material stack mentioned above. The block mask can be removed and thereafter a second block mask can be formed in the area previously processes and processing of either the first or second precursor material stack can be performed.

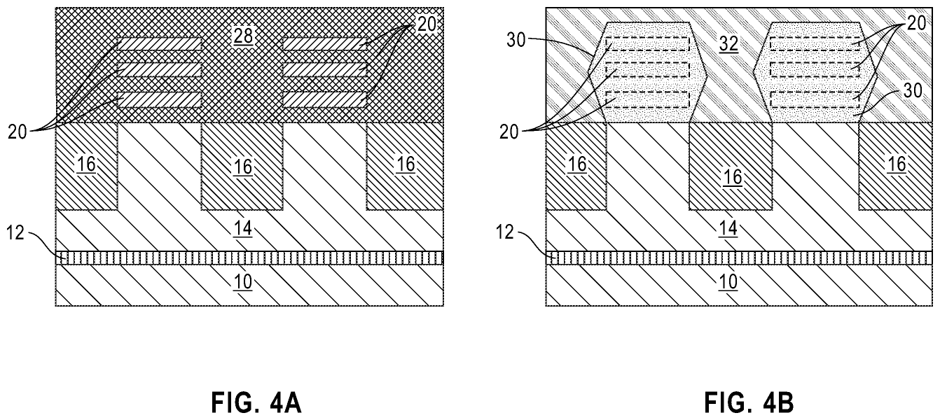

Referring now to FIG. 4A, there is illustrated the first exemplary structure shown in FIG. 2 after performing a replacement gate process. FIG. 4B illustrates the first exemplary structure shown in FIG. 4A and through cut B-B present shown in FIG. 1. The replacement gate process includes removing the sacrificial gate structure and the sacrificial liner 22, further removing the first sacrificial semiconductor material nanosheets 18 to suspend a middle portion of each first semiconductor channel material nanosheet 20 and forming a first gate structure 28 around each of the suspended first semiconductor channel material nanosheets 20. In FIG. 4A, the first gate structure 28 contacts four surfaces (i.e., two end walls, a bottommost surface and a topmost surface) of each first semiconductor channel material nanosheet 20. The replacement gate process further includes forming first source/drain regions 30 and a first frontside interlayer dielectric (ILD) layer 32 as shown in FIG. 4B.

The sacrificial liner 22 can be removed utilizing any material removal process that is selective in removing the dielectric material that provides the sacrificial liner 22. The first sacrificial semiconductor material nanosheets 18 can be removed utilizing any material removal process that is selective in removing the fourth semiconductor material that provides each first sacrificial semiconductor material nanosheet 18.

The first gate structure 28 includes at least a first gate dielectric material layer and a first gate electrode; the first gate dielectric material layer and the first gate electrode are not separately illustrated in the drawings of the present application. As is known, the gate dielectric material layer of a gate structure is in direct contact with each semiconductor channel material nanosheet, and the gate electrode is located on the gate dielectric material layer. In some embodiments, the first gate structure includes a work function metal (WFM) layer (not shown) located between the first gate dielectric material layer and the first gate electrode. In other embodiments, the WFM layer is used solely as the first gate electrode.

The first gate dielectric material layer of the first gate structure 28 is composed of a first gate dielectric material such as, for example silicon oxide, or a first gate dielectric material having a dielectric constant greater than 4.0 (such dielectric materials can be referred to as a high-k gate dielectric material). All dielectric constants mentioned herein are measured in a vacuum unless otherwise stated. Illustrative examples of high-k gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The high-k gate dielectric material can further include dopants such as lanthanum (La), aluminum (Al) and/or magnesium (Mg).

The first gate electrode of the first gate structure 28 can include a first electrically conductive metal-containing material including, but not limited to, tungsten (W), titanium (Ti), tantalum (Ta), ruthenium (Ru), zirconium (Zr), cobalt (Co), copper (Cu), aluminum (Al), lead (Pb), platinum (Pt), tin (Sn), silver (Ag), or gold (Au), tantalum nitride (TaN), titanium nitride (TiN), tantalum carbide (TaC_{X}), titanium carbide (TiC), titanium aluminum carbide, tungsten silicide (WSi₂), tungsten nitride (WN), ruthenium oxide (RuO₂), cobalt silicide, or nickel silicide.

In some embodiments, a WFM layer can be employed as either the first gate electrode or as a separate layer that is located between the first gate dielectric material layer and the first gate electrode. The WFM layer can be used to set a threshold voltage of the FET to a desired value. In some embodiments, the WFM layer can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM layer can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The first gate structure 28 can be formed by deposition, followed by a planarization process.

Each first source/drain region 30 is formed outward from the sidewalls of the first semiconductor channel material nanosheets 20 (this is shown in FIG. 4B in which the first semiconductor channel material nanosheets 20 are shown as dotted lines denoting that they would be present behind the first source/drain regions 30). As used herein, a “source/drain or S/D” region can be a source region or a drain region depending on subsequent wiring and application of voltages during operation of the field effect transistor (FET). As is known, source/drain regions are located on each side of a gate structure. In the present drawings, the corresponding source/drain region of a particular transistor is located in the plane of the drawings. The first source/drain regions 30 is composed of an eighth semiconductor material and a first dopant. The eighth semiconductor material that provides each first source/drain region 30 can include one of the semiconductor materials mentioned for the semiconductor base layer 10. The eighth semiconductor material that provides the first source/drain regions 30 can be compositionally the same as, or compositionally different from, each first semiconductor channel material nanosheet 20. The first dopant that is present in the first source/drain regions 30 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, the first source/drain regions 30 can have a dopant concentration of from 4×10¹⁹ atoms/cm³ to 3×10²² atoms/cm³. The first source/drain regions 30 can be formed by an epitaxial growth process in which the first dopant is typically, but not necessarily, always added during the epitaxial growth process.

The first frontside ILD layer 32 can be composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. The first frontside ILD layer 32 can be formed by a deposition process such as, for example, CVD, PECVD or spin-on coating. A planarization process (such as, for example, chemical mechanical polishing (CMP)) can follow the deposition of the dielectric material that provides the first frontside ILD layer 32.

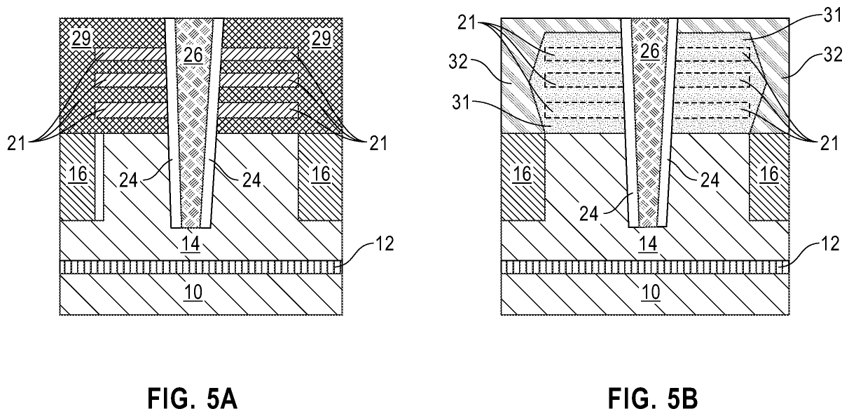

Referring now to FIG. 5A, there is illustrated the second exemplary structure shown in FIG. 3 after performing a replacement gate process. FIG. 5B illustrates the second exemplary structure shown in FIG. 5A and through cut B-B shown in FIG. 1. The replacement gate process includes removing the sacrificial liner 22, removing the second sacrificial semiconductor material nanosheets 19 to suspend each second semiconductor channel material nanosheet 21 and forming a second gate structure 29 around each of the suspended second semiconductor channel material nanosheets 21. In FIG. 5A, the second gate structure 29 contacts three surfaces (i.e., one of the end walls, a bottommost surface and a topmost surface) of each second semiconductor channel material nanosheet 21. The replacement gate process further includes forming second source/drain regions 31 and the first frontside ILD layer 32 as shown in FIG. 5B.

The sacrificial liner 22 can be removed utilizing any material removal process that is selective in removing the dielectric material that provides the sacrificial liner 22. The second sacrificial semiconductor material nanosheets 19 can be removed utilizing any material removal process that is selective in removing the sixth semiconductor material that provides second sacrificial semiconductor material nanosheets 19.

The second gate structure 29 includes at least a second gate dielectric material layer and a second gate electrode; the second gate dielectric material layer and the second gate electrode are not separately illustrated in the drawings of the present application. In the present application, the second gate dielectric material layer is composed of a second gate dielectric material. The second gate dielectric material includes one of the first gate dielectric materials mentioned above. In the present application, the second gate dielectric material can be compositionally the same as, or compositionally different from, the first gate dielectric material. The second gate electrode is composed of a second electrically conductive metal-containing material. The second electrically conductive metal-containing material includes one of the first electrically conductive metal-containing material mentioned above. In the present application, the second electrically conductive metal-containing material can be compositionally the same as, or compositionally different from, the second electrically conductive metal-containing material. The second gate structure 29 can be formed by deposition, followed by a planarization process.

Each second source/drain region 31 is formed outward from sidewalls of the second semiconductor channel material nanosheets 21 (this is shown in FIG. 5B in which the second semiconductor channel material nanosheets 21 are shown as dotted lines denoting that they would be present behind the second source/drain regions 31. As is shown in FIG. 5B, one sidewall of the second source/drain regions 31 can be in direct physical contact with the dielectric layer 24 of the dielectric pillar structure. The second source/drain regions 31 is composed of a ninth semiconductor material and a second dopant. The ninth semiconductor material that provides each second source/drain region 31 can include one of the semiconductor materials mentioned for the semiconductor base layer 10. The ninth semiconductor material that provides the second source/drain regions 31 can be compositionally the same as, or compositionally different from, each second semiconductor channel material nanosheet 21. The ninth semiconductor material can be compositionally the same, or compositionally different from, the eighth semiconductor material. The second dopant that is present in the second source/drain regions 31 can be either a p-type dopant or an n-type dopant, both as defined above. The second dopant can be of a same conductivity type as, or a different conductivity type than, the first dopant. The second source/drain regions 31 can be formed by an epitaxial growth process in which the second dopant is typically, but not necessarily, always added during the epitaxial growth process.

The first frontside ILD layer 32 is as defined above and the first frontside ILD layer 32 can be formed utilizing the same processing as mentioned above for forming the same layer in the first exemplary structure.

In embodiments in which the first and second exemplary structures are integrated together, the replacement gate processing of the first exemplary structure can be performed prior to, simultaneously with, or after the replacement gate processing of the second exemplary structure. Block mask technical can be employed when the replacement gate processing of the first and second exemplary structure are not performed at the same time.

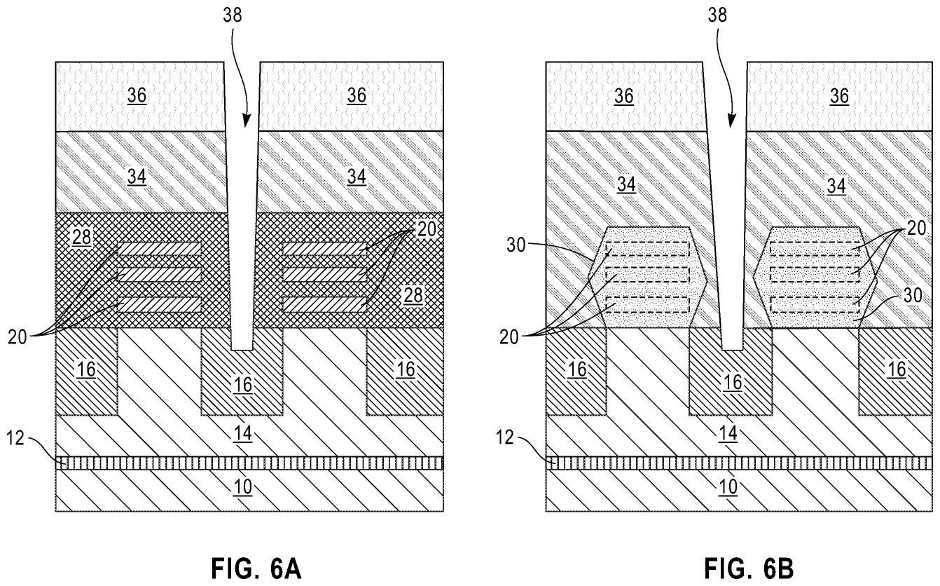

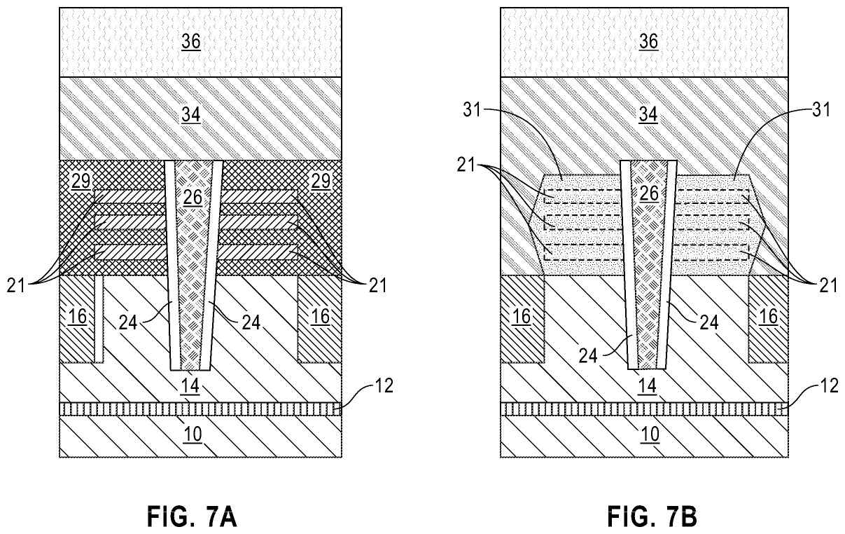

Referring now to FIGS. 6A-6B, there are illustrated the first exemplary structure shown in FIGS. 4A-4B, respectively, after performing a gate cut process. FIGS. 7A-7B illustrate the second exemplary structure shown in FIGS. 5A-5B, respectively, after performing the gate cut process to the first exemplary structure. Note that in cases in which the first exemplary structure is not integrated with the second exemplary structure the gate cut process can be omitted since cut cutting is not typically performed in the area including the second exemplary structure. Prior to performing the gate cut process, additional ILD material is formed on the physically exposed first gate structure 28 and the first frontside ILD layer 32 in the area including the first exemplary structure and the physically exposed second gate structure 29 and the first frontside ILD layer 32 in the area including the second exemplary structure. The additional ILD material includes one of the dielectric materials mentioned above for the first frontside ILD layer 32. Collectively, the first frontside ILD layer 32 and the additional ILD material provides a middle-of-the-line (MOL) dielectric layer 34 to the first exemplary structure and to the second exemplary structure. Next, a masking layer 36 is formed on the MOL dielectric layer 34. Masking layer 36 can be composed of a masking material or a combination of masking materials can be used. In one example, masking layer 36 can include an organic planarization material. The masking layer 36 can be formed by a deposition process such as, for example, CVD, PECVD or spin-on coating. An opening is then formed (by lithography and etching) in the masking layer 36 in the area including the first exemplary structure by lithography and etch. The opening physically exposes the first gate structure 28 and the first frontside ILD layer 32. The gate cut process continues by etching a gate cut trench 38 into the MOL dielectric layer 34, the first gate structure 28 and a portion of the shallow trench isolation structure 16 as shown in FIG. 6A. Masking layer 36 can then be removed utilizing any conventional masking material removal process.

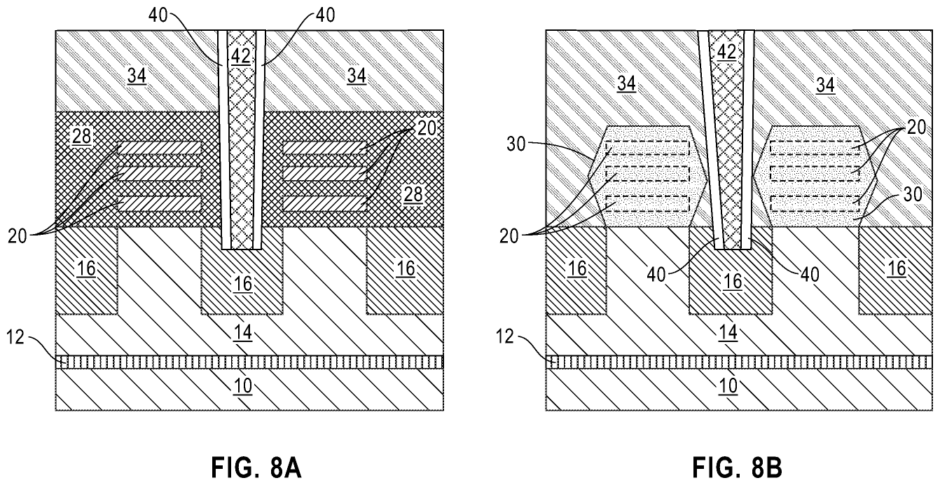

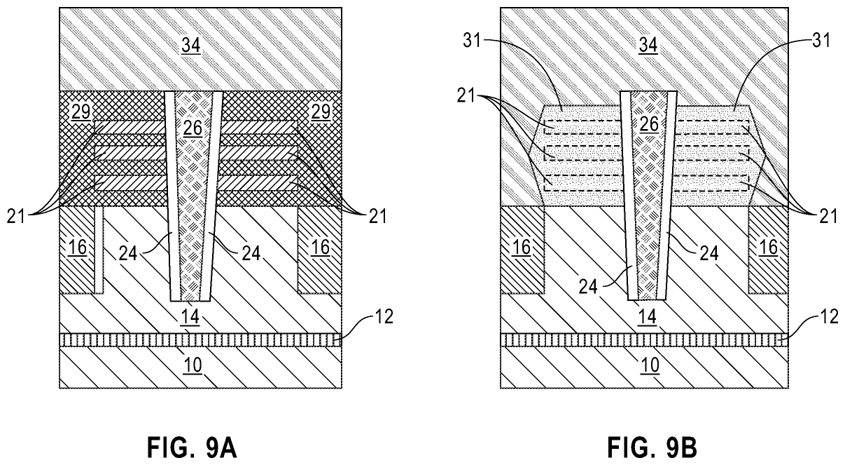

Referring now to FIGS. 8A-8B, there are illustrated the first exemplary structure shown in FIGS. 6A-6B, respectively, after performing a gate cut trench fill process. FIGS. 9A-9B illustrates the second exemplary structure shown in FIGS. 7A-7B, respectively, after performing the gate cut trench fill process to the first exemplary structure. Note that in cases in which the first exemplary structure is not integrated with the second exemplary structure the gate cut trench fill process can be omitted. The gate cut trench fill process includes removing the masking layer 36 and forming a gate cut trench structure in the gate cut trench 38. Next, the gate cut trench structure is formed that includes a gate cut dielectric core material 42 that is bounded between a pair of gate cut trench dielectric layers 40. The gate cut dielectric core material 42 can be composed of one of the second dielectric materials mentioned above for the sacrificial dielectric core 26 of the dielectric pillar structure. Each gate cut trench dielectric layer 40 can be composed of one of the first dielectric materials mentioned above for the dielectric layer 24 of the dielectric pillar structure. The gate cut trench structure can be formed utilizing the same processing steps mentioned above for forming the dielectric pillar structure. Following the formation of the gate cut trench structure, a planarization process can be performed.

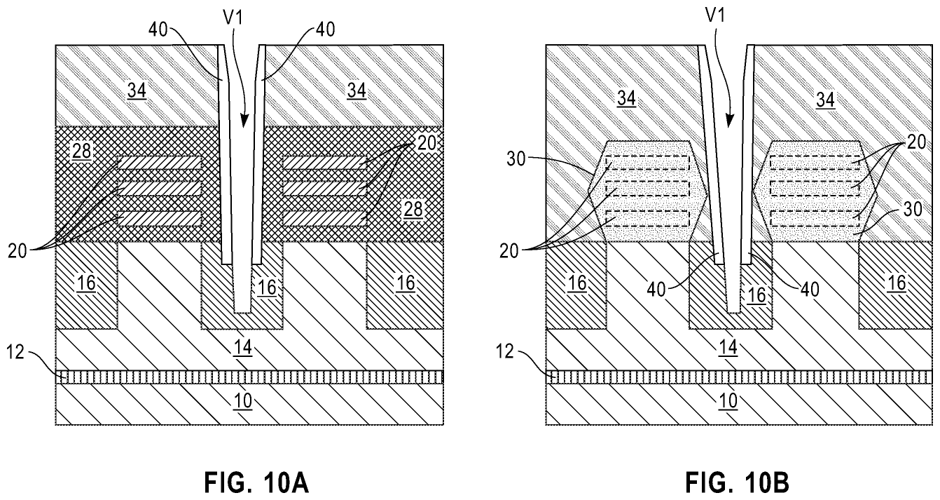

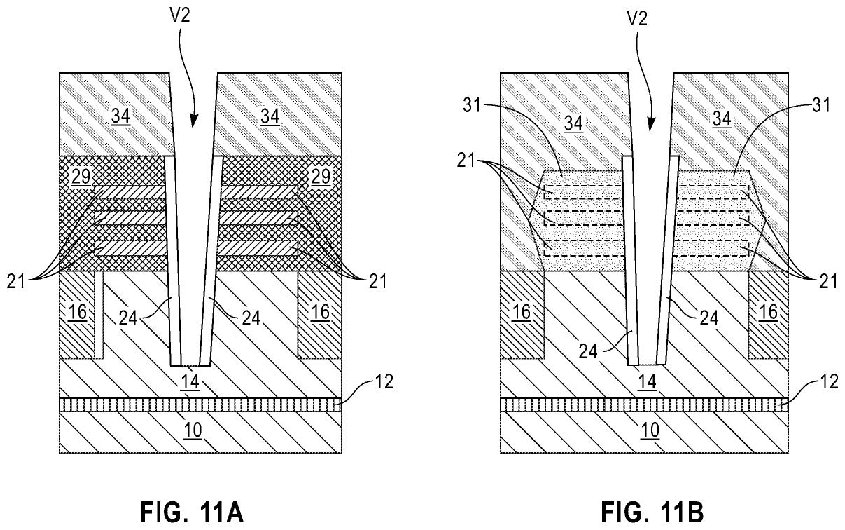

Referring now to FIGS. 10A-10B, there are illustrated the first exemplary structure shown in FIGS. 8A-8B, respectively, after forming a first via opening V1. FIGS. 11A-11B illustrate the second exemplary structure shown in FIGS. 9A-9B, respectively, after forming a second via opening V2. In the present application, an upper portion of the second via opening V2 that is located in the MOL dielectric layer 34 can have a shape that differs from a remaining portion of the second opening V2 that is located between the dielectric layer 24. In embodiments, the shape of the upper portion of the second via opening V2 that is located in the MOL dielectric layer 34 can be reversed trapezoid. The forming of the first via opening V1 can be performed at the same time as, or at a different time from, the forming of second via opening V2. In some embodiments, the forming of the first and second via openings includes forming (by lithography and etching) an opening in the MOL dielectric layer 34 in the area including the second exemplary structure that physically exposes a surface of sacrificial dielectric core 26 of the dielectric pillar structure. An etch is then used to remove both the sacrificial dielectric core 26 and the gate cut dielectric core material 42. As shown in FIGS. 10A-10B, the first via opening V1 has a bottommost wall that is defined by a sub-surface of the shallow trench isolation structure 16. As shown in FIGS. 11A-11B, the second via opening V2 has a bottommost wall that is defined by a sub-surface of the semiconductor device layer 14. In the present application, the depth of V1 is less than the depth of V2. As shown in FIGS. 11A-11B, a portion of the MOL dielectric layer 34 is located on a topmost surface of the dielectric layer 24 of the dielectric pillar structure.

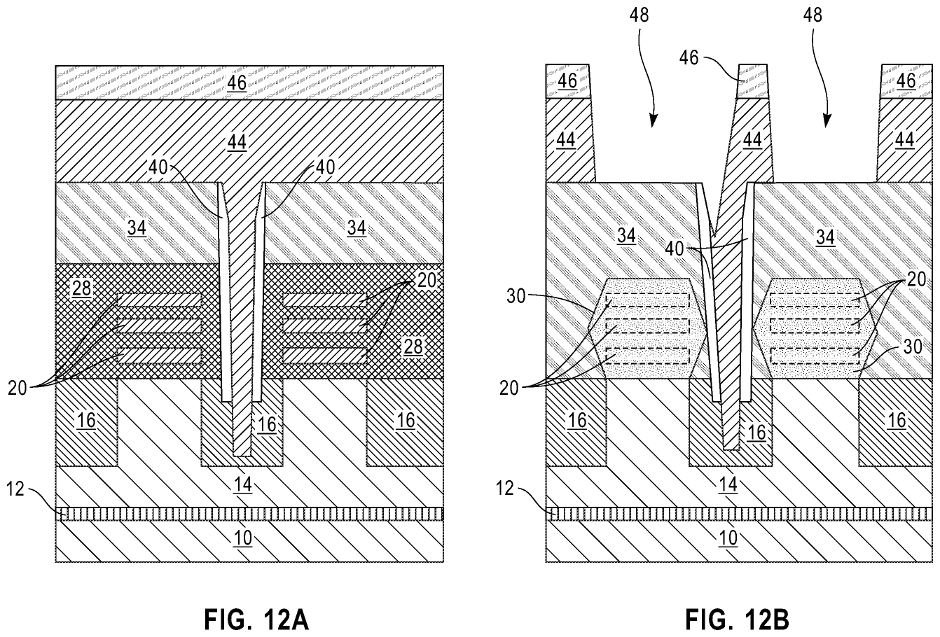

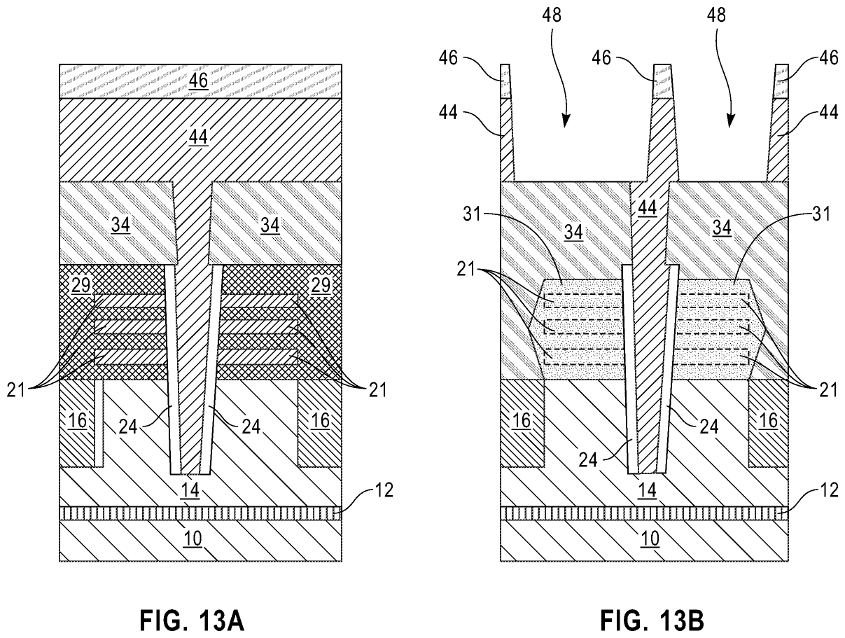

Referring now to FIGS. 12A-12B, there are illustrated the first exemplary structure shown in FIGS. 10A-10B, respectively, after forming a frontside source/drain contact mask. FIGS. 13A-13B illustrate the second exemplary structure shown in FIGS. 11A-11B, respectively, after forming the frontside source/drain contact mask. The frontside source/drain contact mask can include a first frontside source/drain contact masking layer 44 and a second frontside source/drain contact masking layer 46. In some embodiments, the first frontside source/drain contact masking layer 44 can be composed of an organic planarization material, and the second frontside source/drain contact masking layer 46 can be composed of an anti-reflective coating (ARC) material. The frontside source/drain contact mask can be formed by deposition of the first frontside source/drain contact masking layer 44 and the second frontside source/drain contact masking layer 46 and thereafter the first frontside source/drain contact masking layer 44 and the second frontside source/drain contact masking layer 46 are patterned by lithography and etching to include openings 48. Each opening 48 physically exposes the MOL dielectric layer 34 that is located above the first source/drain regions 30 and above the second source/drain regions 31. With the area including the first exemplary structure, each opening 48 in the frontside source/drain contact mask can also physically expose a topmost surface of the gate cut trench dielectric layer 40 as shown in FIG. 12B.

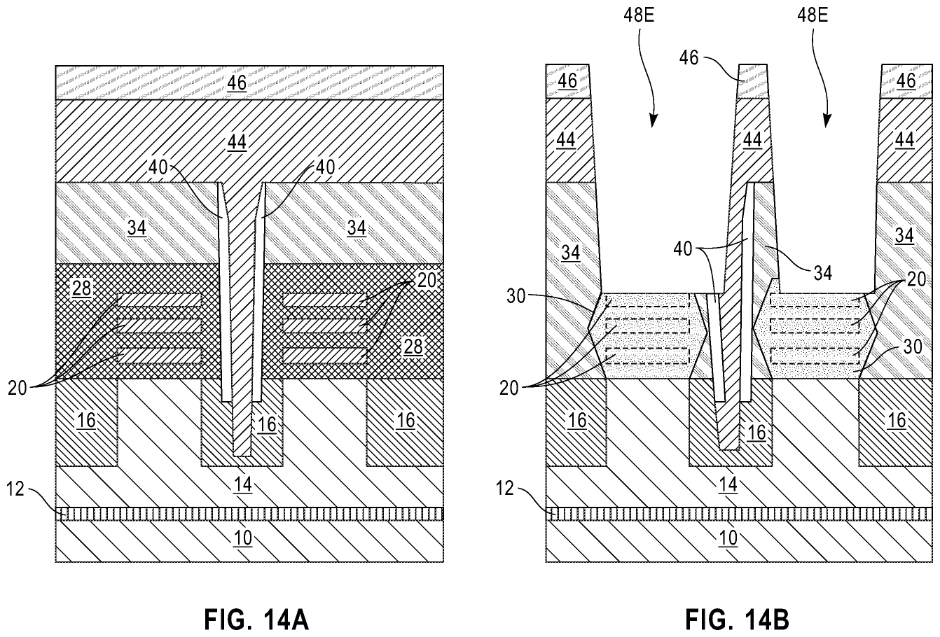

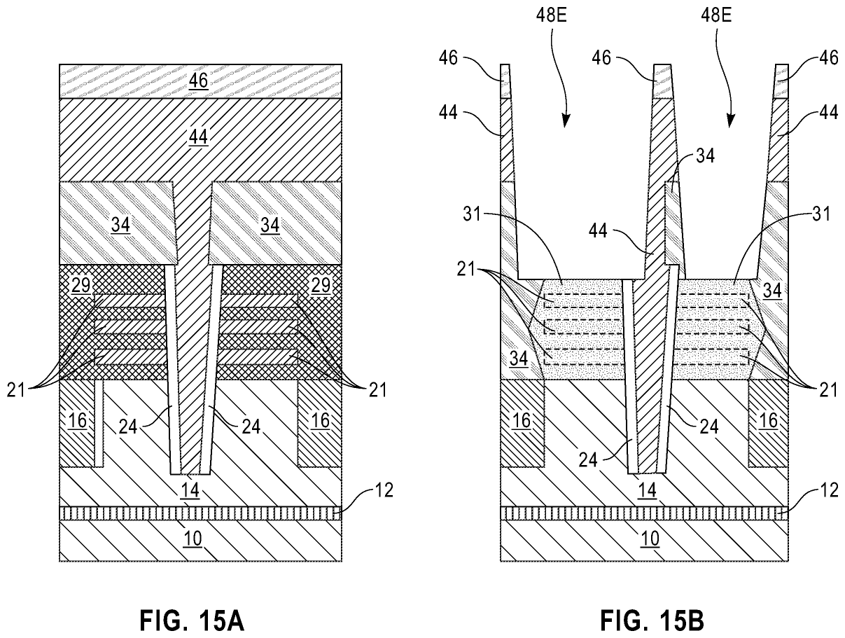

Referring now to FIGS. 14A-14B, there are illustrated the first exemplary structure shown in FIGS. 12A-12B, respectively, after performing a frontside source/drain contact etch. FIGS. 15A-15B illustrate the second exemplary structure shown in FIGS. 13A-13B, respectively, after performing the frontside source/drain contact etch. The frontside source/drain contact etch includes an etch that is selective in removing the physically exposed portion of the MOL dielectric layer 34. The etch can also remove an upper portion of the first source/drain regions 30, an upper portion of the second source/drain regions 31, an upper portion of the gate cut trench dielectric layer 40 and an upper portion of the dielectric layer 24 as shown in FIGS. 14B and 15B. The etch forms extended openings 48E. The etch can form gate cut trench dielectric layers 40 of different heights as shown in FIG. 14B, and dielectric layers 24 of different heights as shown in FIG. 15B. As shown in FIG. 14B, a reduced height gate cut trench dielectric layers 40 is formed that is adjacent to one of the first source/drain regions 30, and a reduced height dielectric layer 24 is formed adjacent to one of the second source/drain regions 31.

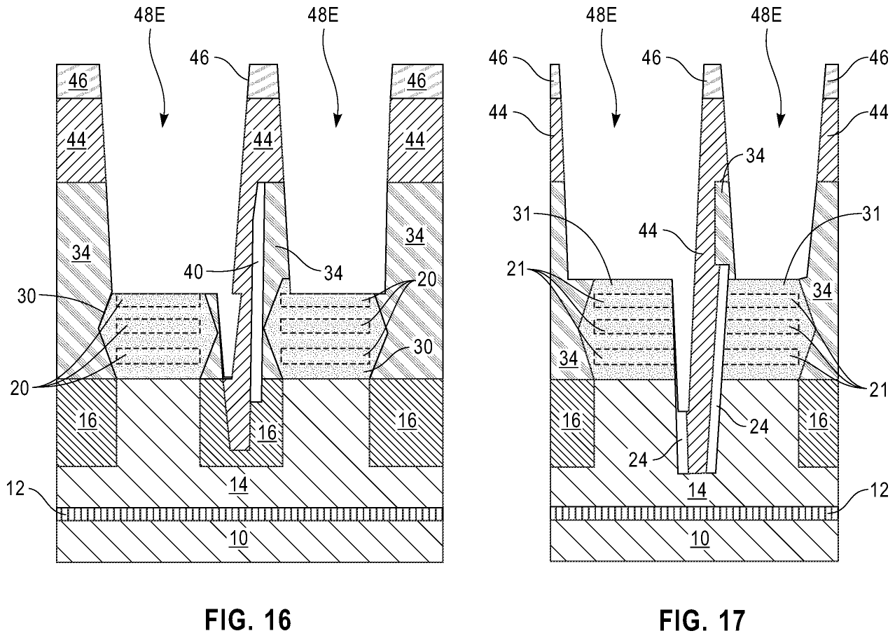

Referring now to FIG. 16, there is illustrated the first exemplary structure shown in FIG. 14B after performing an optional etch. FIG. 17 illustrates the second exemplary structure shown in FIG. 15B after performing this same optional etch. In the area including the first exemplary structure, this optional etch can remove substantially all of the gate cut trench dielectric layer 40 adjacent to one of the first source/drain regions 30. In the area including the second exemplary structure, this optionally etch can reduce the height of the dielectric layer 24 such that the dielectric layer 24 is no longer adjacent to one of the second source/drain regions 31. In some embodiments, the optional etch can also remove the entirety of the dielectric layer 24 that is subjected to the optional etch.

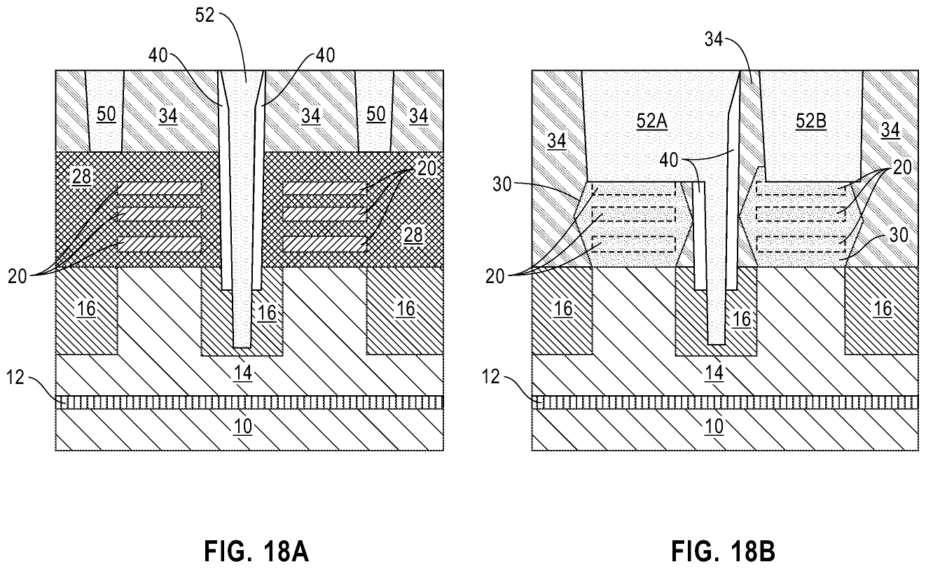

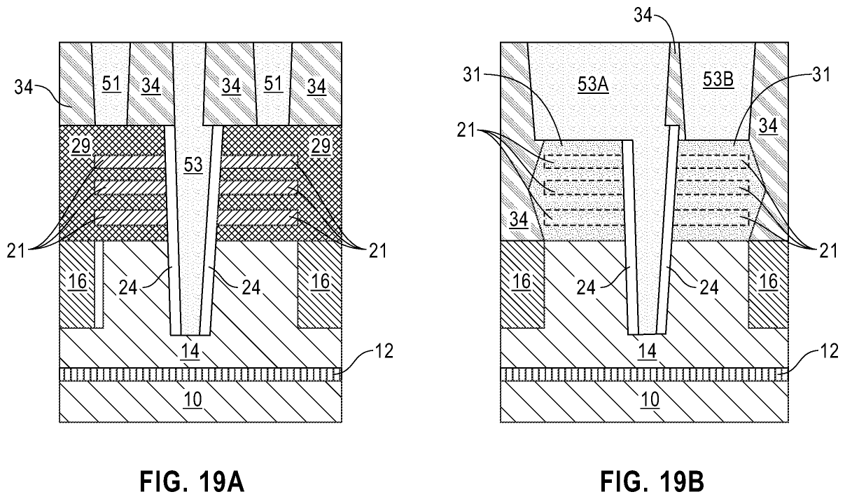

Referring now to FIGS. 18A-18B, there are illustrated the first exemplary structure shown in FIGS. 14A-14B, respectively, after forming frontside contact structures including VBPR structures. FIGS. 19A-19B illustrates the second exemplary structure shown in FIGS. 15A-15B, respectively, after forming frontside contact structures including VBPR structures. Note that structures shown in FIGS. 16 and 17 could be used and forming frontside contact structures could be formed in those structures as well. The forming of the frontside contact structures includes first removing the frontside source/drain contact mask utilizing a material removal process or combination of material removal processes that is (are) selective in removing the frontside source/drain contact mask. The frontside contact structures are then formed as described herein below.

In the area including the first exemplary structure, the frontside contact structures include first frontside gate contact structures 50, a first frontside source/drain contact structure 52A that is merged with a first VBPR structure 52, and a second frontside source/drain contact structure 52B. The first VBPR structure 52 is present in the non-active device area that is located between two adjacent first gate structures 28. In the area including the second exemplary structure, the frontside contact structures include second frontside gate contact structures 51, a third frontside source/drain contact structure 53A that is merged with a second VBR structure 53, and a fourth frontside source/drain contact structure 53B. In the present application, an upper portion of second VBR structure 53 that is adjacent to the active device area and present in the MOL dielectric layer 34 can have shape that differs from the remaining portion of the second VBR structure 53 that is present between the dielectric layers 24. In embodiments of the present application, the shape of the portion of second VBR structure 53 that is adjacent to the active device area and present in the MOL dielectric layer 34 can be reversed trapezoid.

The first frontside gate contact structure 50 directly contacts the first gate electrode of the first gate structure 28, the second frontside gate contact structure 51 directly contacts the second gate electrode of the second gate structure 29, the first frontside source/drain contact structure 52A that is merged with first VBPR structure 52 directly contacts a physically exposed surface (typically a topmost surface) of one of the first source/drain regions 30, the second frontside source/drain contact 52B directly contacts another first source/drain region 30, the third frontside source/drain contact structure 53A that is merged with the second VBPR structure 53 directly contacts a physically exposed surface (typically a topmost surface) of one of the second source/drain regions 31, and the fourth frontside source/drain contact 53B directly contacts another second source/drain region 31.

The frontside contact structures (i.e., frontside gate contact structures, frontside source/drain contact structures and the VBPR structures) can include a contact conductor material such as, for example, W, Cu, Al, Co, Ru, Mo, Os, Ir, Rh, or an alloy thereof. In embodiments, the frontside contact structures can also include a silicide liner such as TiSi, NiSi, NiPtSi, etc., and an adhesion metal liner, such as Ti, Ta, TiN, TiN or any combination thereof. The contact conductor material can be formed by any suitable deposition method such as, for example, atomic layer deposition (ALD), CVD, physical vapor deposition (PVD) or plating. The frontside gate contact structures are formed by forming (by lithography and etching) a contact opening in the MOL dielectric layer 34 that extends down to the gate electrode of the respective gate structure. The contact opening can then by filled with at least the contact conductor material mentioned above. After filling of the contact openings with at the contact conductor material, a planarization process can be employed. The second and fourth frontside source/drain contact structures can be formed by forming (by lithography and etching) a contact opening in the MOL dielectric layer 34 that extends down to one of the source/drain regions. The contact opening can then by filled with at least the contact conductor material mentioned above. After filling of the contact openings with at the contact conductor material, a planarization process can be employed.

The first VBPR structure 52 including the frontside first source/drain contact structure 52A can be formed by filling the extended openings 48E and the first via opening V1 with at least one of the contact conductor materials mentioned above. After filling of the extended openings 48E and the first via opening V1 with at the contact conductor material, a planarization process can be employed. The second VBPR structure 53 including the frontside third source/drain contact structure 53A can be formed by filling the extended openings 48E and the second via opening V2 with at least one of the contact conductor materials mentioned above. After filling of the extended openings 48E and the second via opening V2 with at the contact conductor material, a planarization process can be employed.

In some embodiments, the frontside gate contact structure, the frontside source/drain contact structures and the VBPR structures are formed at the same time. In other embodiments, the frontside gate contact structures and/or the frontside source/drain contact structures can be formed prior to, or after, the forming of the VBPR structure.

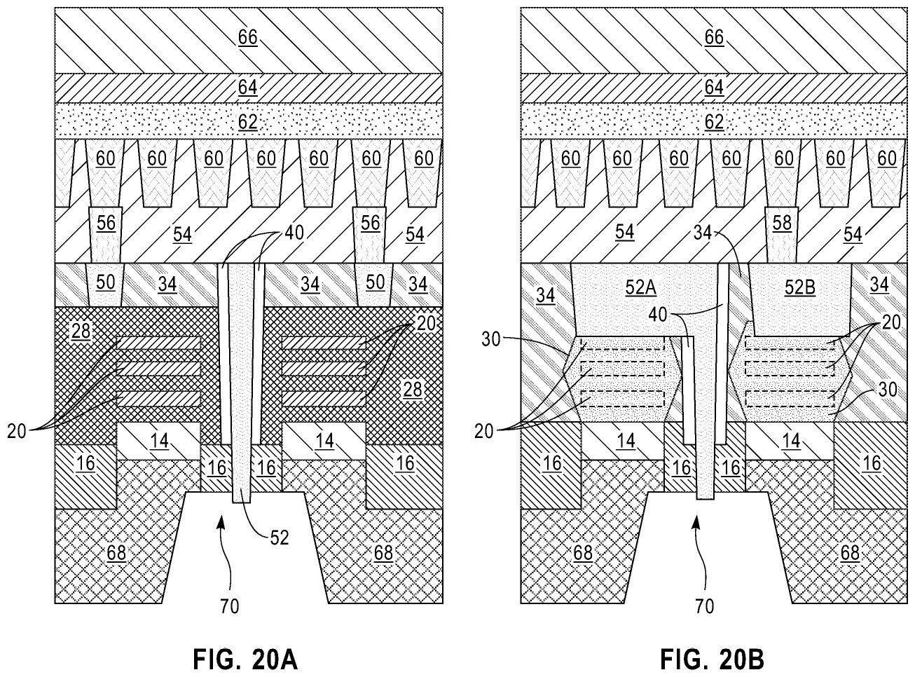

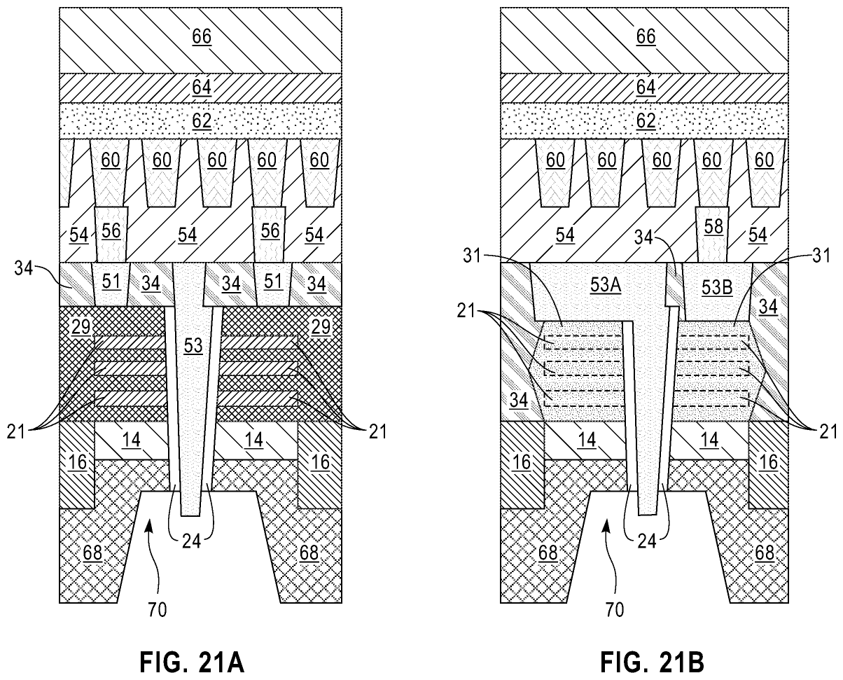

Referring now to FIGS. 20A-20B, there are illustrated the first exemplary structure shown in FIGS. 18A-18B, respectively, after additional frontside processing and then performing backside processing. FIGS. 21A-21B illustrate the second exemplary structure shown in FIGS. 19A-19B, respectively, after additional frontside processing and then performing backside processing. The additional frontside processing includes forming a lower frontside back-end-of-the-line (BEOL) level that includes metal lines 60, first metal vias 56 and second metal vias 58 embedded in an interconnect dielectric layer 54, upper frontside BEOL level 62, optional bonding layer 64 and carrier wafer 66. In the present application, the lower frontside BEOL level that includes metal lines 60, first metal vias 56 and second metal vias 58 embedded in an interconnect dielectric layer 54 and the upper frontside BEOL level 62 provide a frontside BEOL structure.

In the present application, the first metal vias 56 are vias that have a first surface that is in electrically connected to one of the metal lines 60 and a second surface, opposite the first surface, that is electrically connected to one of the frontside gate contact structures (the first frontside gate contact structure 50 and the second frontside gate contact structures 51), and the second metal vias 58 are vias that have a first surface that is in electrically connected to one of the metal lines 60 and a second surface, opposite the first surface, that is electrically connected to the second and fourth frontside source/drain contact structures. The first and second metal vias and the metal lines 60 are composed of electrically conductive materials such as Cu, Co, W, or Ru, with a thin metal adhesion liner such as TiN/TaN located along at least the sidewalls of the metal vias and the metal lines 60. The interconnect dielectric layer 54 includes any conventional interconnect dielectric material that is well known to those skilled in the art. The lower frontside BEOL level can be formed utilizing a BEOL process that is well known in the art.

Next, upper frontside BEOL level 62 including one or more interconnect dielectric layers that contain one or more wiring/vias regions embedded thereon (the various interconnect dielectric layers and the wiring/via regions are not independently shown). The upper frontside BEOL level 62 can be formed utilizing BEOL processing techniques that are well known to those skilled in the art. The carrier wafer 66 can include one of the semiconductor materials mentioned above for the semiconductor base layer 10. In the present application, the carrier wafer 66 can be bonded to upper frontside BEOL levels 62 via bonding layer 64. Bonding layer 64 can be a bonding oxide that is applied to either or both the upper frontside BEOL levels 62 and the carrier wafer 66 prior to bonding.

Backside processing includes flipping the exemplary structures (to expose a backside of substrate), entirely removing the semiconductor base layer 10 (if present) and the etch stop layer 12 (if present), and partially removing the semiconductor device layer 14. The remaining semiconductor device layer 14 has a depth that is less than depth of the shallow trench isolation structure 16. Flipping of the structures can be performed by hand or by utilizing a mechanical means such as, for example, a robot arm. The removal of the semiconductor base layer 10 can be performed utilizing a material removal process that is selective in removing the first semiconductor material that provides the semiconductor base layer 10. After removal of the semiconductor base layer 10, a surface of the etch stop layer 12 is physically exposed. The physically exposed etch stop layer 12 is removed utilizing a material removal process that is selective in removing the etch stop layer 12. The partially removal of the semiconductor device layer 14 includes a material removal process that is selective in removing the second semiconductor material that provides the semiconductor device layer 14. These removal steps physically exposed the first and second VBPR structures as shown in FIGS. 20A-21B.

After the partial removal of the semiconductor device layer 14, a first backside ILD layer 68 is formed embedding the first and second VBPR structures and thereafter openings 70 are formed that re-expose the first and second VBPR structures. The first backside ILD layer 68 is composed of one of the dielectric materials mentioned above for the first frontside ILD layer 32. The first backside ILD layer 68 can be formed utilizing a deposition process as described above in forming the first frontside ILD layer 32. Openings 70 are formed by lithography and etching.

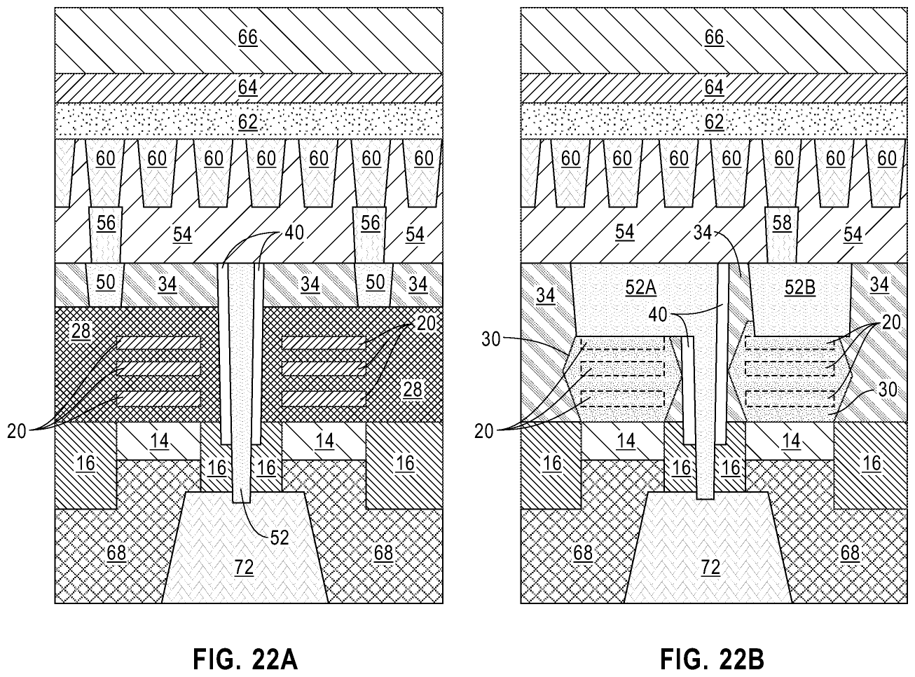

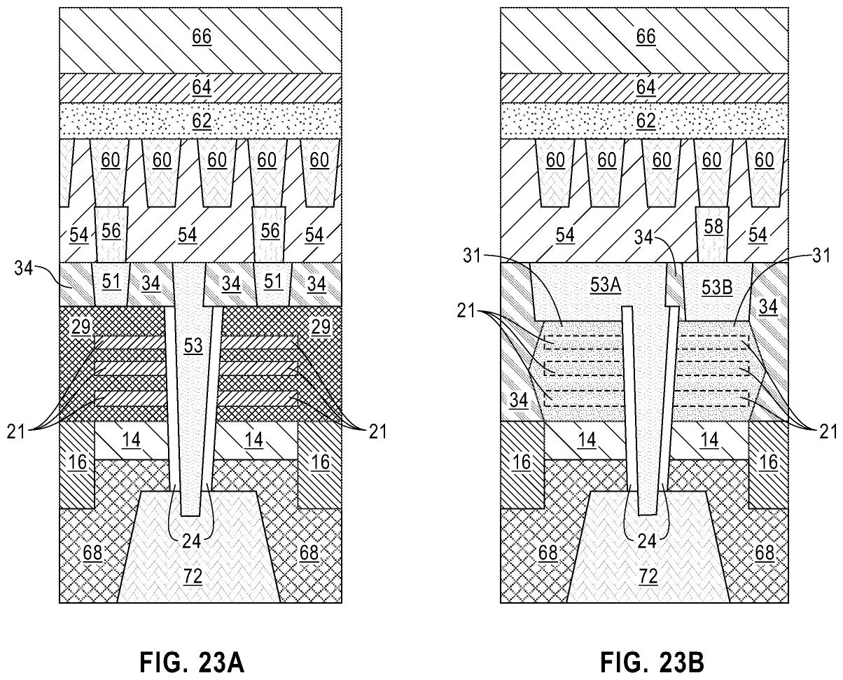

Referring now to FIGS. 22A-22B, there are illustrated the first exemplary structure shown in FIGS. 20A-20B, respectively, after forming backside power rails 72 to provide power to the nanosheet transistor. FIGS. 23A-23B illustrate the second exemplary structure shown in FIGS. 21A-21B, respectively, after forming backside power rails 72 to provide power to the fork sheet transistor. As is illustrated in FIG. 23A-23B, the dielectric layer 24 lands on a surface of one of the backside power rails 72. As is also illustrated in FIG. 23A-23B, the second VBPR structure 53 extends into one of the backside power rails 72. The first VBPR structure 52 also extends into one of the backside power rails 72. Unlike the dielectric layer 24 present in the second exemplary structure, the gate cut trench dielectric layer 40 does not land on one of the backside power rails 72. The backside power rails 72 are composed of an electrically conductive power rail material including, but not limited to, W, Co, Ru, Al, Cu, Pt, Rh, or Pd with a thin metal adhesion layer, such as TiN, TaN, etc. The backside power rails 72 can be formed by filling each of the openings 70 with one of the electrically conductive power rail materials, and the performing a planarization process. In the area including the first exemplary structure, the backside power rail is in electrical connection with the nanosheet transistor by means of the first the first VBPR structure 52 that is merged with the first frontside source/drain contact structure 52A. Notably, the first frontside source/drain contact structure 52A forms a direct contact with a topmost surface of one of the first source/drain regions 30. In the area including the second exemplary structure, the backside power rail is electrical connection with the fork sheet transistor by means of the second VBPR structure 53 that is merged with the third frontside source/drain contact structure 53A. Notably, the third frontside source/drain contact structure 53A forms a direct contact with a topmost surface of one of the second source/drain regions 31.

In one embodiment (See, for example, 23A-23B), a semiconductor structure is provided that includes a fork sheet transistor located on a frontside of semiconductor device layer 14 and including a plurality of semiconductor channel material nanosheets (i.e., second semiconductor channel material nanosheets 21 on the left hand side of FIGS. 23A-23B), a gate structure (i.e., second gate structure 29 on the left hand side of FIGS. 23A-23B) contacting each semiconductor channel material nanosheet (i.e., second semiconductor channel material nanosheets 21) of the plurality of semiconductor channel material nanosheets, and source/drain regions (second source/drain region 31 on the left hand side of FIG. 23B). The gate structure and the plurality of semiconductor channel material nanosheets are located in an active device area and each source/drain region is located in a source/drain area that is adjacent to the active device area. The semiconductor structure further includes backside power rail 72 located on a backside of the semiconductor device layer 14, and a VBPR structure (i.e., second VBPR structure 53 shown in FIGS. 23A-23B) located in a non-active device area that is adjacent to both the active device area and the source/drain area. In accordance with the present application, the VBPR structure is in electrical contact with the backside power rail 72 and one of the source/drain regions (i.e., the second source/drain region 31 on the left hand side of FIG. 23B) of the fork sheet transistor. The semiconductor structure further includes dielectric layer 24 separating the VBPR structure (i.e., second VBPR structure 53) from each of the gate structure (i.e., the second gate structure 29), the plurality of semiconductor channel material nanosheets, the semiconductor device layer 14 and the source/drain region that is in electrical contact with the backside power rail 72. The structure of the present application effectively take advantages of the scaling benefits of fork sheet transistors and improves the process caused aspect ratio from separate nanosheet transistors. Also, contact resistance can be improved.

In embodiments of the present application (See, for example, FIG. 23A), an upper portion of the VBPR structure (i.e., the second VBPR structure 53) is present in MOL dielectric layer 34, and the upper portion of the VBPR structure directly contacts the MOL dielectric layer 34.

In embodiments of the present application (See, for example, FIG. 23A), the upper portion of the VBPR structure (i.e., the second VBPR structure 53) that is present in the MOL dielectric layer 34 has a shape that differs from a shape of a remaining portion of the VBPR structure. The different shape improves overlay margin.

In embodiments of the present application (See, for example, FIG. 23B), the VBPR structure (i.e., the second VBPR structure 53) includes a merged frontside source/drain contact structure (i.e., third frontside source/drain contact structure 53A) in direct physically contact with a topmost surface of the source/drain region (i.e., the second source/drain region 31 on the left hand side of FIG. 23B) that is in electrical contact with the backside power rail 72. This connects the source/drain region from the frontside to the backside power. As such, improved IR drop is obtained as compared to other types of wiring solutions.

In embodiments of the present application (See, for example, FIGS. 23A-23B), the VBPR structure (i.e., the second VBPR structure 53) extends into backside power rail 72. This provides a solution of frontside connection to the backside power rail.

In embodiments of the present application (see, for example, FIGS. 23A-23B), dielectric layer 24 lands on a surface of the backside power rail 72.

In embodiments of the present application (See, for example, FIG. 23A), the structure further includes a frontside BEOL structure (i.e., the lower interconnect level and the upper BEOL level 62 mentioned above) located above the transistor in which the frontside BEOL structure is in electrical contact with the gate structure (i.e., the second gate structure 29) of the transistor by a frontside gate contact structure (i.e., second frontside gate contact structure 51). This structure takes advantage of the gate cut area for signal transfer from the frontside to the backside.

In embodiments of the present application (See, for example, FIGS. 23A-23B), the VBPR structure (i.e., the second VBPR structure 53) is in contact with the frontside BEOL structure.

In embodiments of the present application (See, for example, FIGS. 23A-23B), the dielectric layer 24 as a topmost surface that is substantially coplanar with a topmost surface of the gate structure (i.e., second gate structure 29), and a bottommost surface that lands on the backside power rail 72.

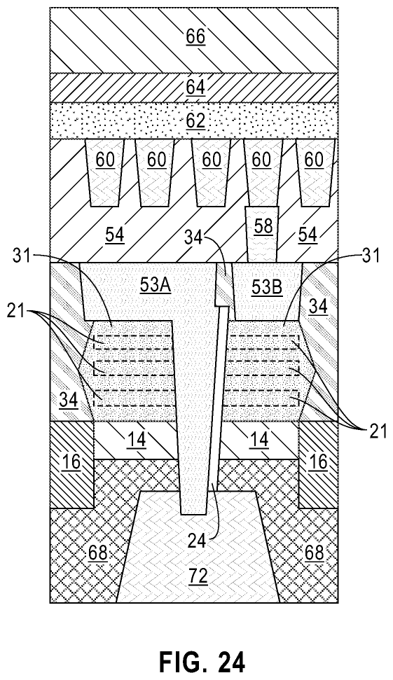

Referring now to FIG. 24, there is illustrated an alternative fork sheet transistor that be formed in the present application. The alternative fork sheet transistor illustrated in FIG. 24 is similar to the exemplary structure illustrated in FIG. 23B except that the dielectric layer 24 is entirely removed such that the second VBPR structure 53 that is located in the source/drain area directly contacts the sidewalls of the second source/drain region 31, the semiconductor device layer 14 and the backside ILD layer 68. It is noted that the active device area for the structure shown in FIG. 24 would be the same as that depicted in FIG. 23A.

Notably, FIG. 24 illustrates a semiconductor structure in accordance with another embodiment. The semiconductor structure illustrated in FIG. 24 (which includes the same structure as shown in the active device area shown in FIG. 23A) includes a fork sheet transistor located on a frontside of semiconductor device layer 14 and including a plurality of semiconductor channel material nanosheets (i.e., second semiconductor channel material nanosheets 21 on the left hand side of FIGS. 23A and 24), a gate structure (i.e., second gate structure 29 on the left hand side of FIGS. 23A and 24) contacting each semiconductor channel material nanosheet (i.e., second semiconductor channel material nanosheets 21) of the plurality of semiconductor channel material nanosheets, and source/drain regions (second source/drain region 31 on the left hand side of FIG. 24). The gate structure and the plurality of semiconductor channel material nanosheets are located in an active device area and each source/drain region is located in a source/drain area that is adjacent to the active device area. The semiconductor structure further includes backside power rail 72 located on a backside of the semiconductor device layer 14, and a VBPR structure (i.e., second VBPR structure 53 shown in FIGS. 23A and 24B) located in a non-active device area that is adjacent to both the active device area and the source/drain area. In accordance with the present application, the VBPR structure is in electrical contact with the backside power rail 72 and one of the source/drain regions (i.e., the second source/drain region 31 on the left hand side of FIG. 24) of the fork sheet transistor. As shown in FIGS. 23A and 24, the semiconductor structure of this embodiment also includes dielectric layer 24 separating the VBPR structure (i.e., second VBPR structure 53 shown in FIGS. 23A and 24) from each of the gate structure, and the plurality of semiconductor channel material nanosheets, which improves contact resistance.

In embodiments of the present application (See, for example, FIG. 23A), an upper portion of the VBPR structure (i.e., the second VBPR structure 53) is present in MOL dielectric layer 34, and the upper portion of the VBPR structure directly contacts the MOL dielectric layer 34.

In embodiments of the present application (See, for example, FIG. 23A), the upper portion of the VBPR structure (i.e., the second VBPR structure 53) that is present in the MOL dielectric layer 34 has a shape that differs from a shape of a remaining portion of the VBPR structure. The different shape improves overlay margin.

In embodiments of the present application (See, for example, FIG. 24), the VBPR structure (i.e., the second VBPR structure 53) includes a merged frontside source/drain contact structure (i.e., third frontside source/drain contact structure 53A) in direct physically contact with a topmost surface of the source/drain region (i.e., the second source/drain region 31 on the left hand side of FIG. 23B) that is in electrical contact with the backside power rail 72. This connects the source/drain region from the frontside to the backside power. As such, improved IR drop is obtained as compared to other types of wiring solutions.

In embodiments of the present application (See, for example, FIGS. 23A and 24), the VBPR structure (i.e., the second VBPR structure 53) extends into backside power rail 72. This provides a solution of frontside connection to the backside power rail.

In embodiments of the present application (see, for example, FIGS. 23A and 24), dielectric layer 24 lands on a surface of the backside power rail 72.

In embodiments of the present application (See, for example, FIG. 23A), the structure further includes a frontside BEOL structure (i.e., the lower interconnect level and the upper BEOL level 62 mentioned above) located above the transistor in which the frontside BEOL structure is in electrical contact with the gate structure (i.e., the second gate structure 29) of the transistor by a frontside gate contact structure (i.e., second frontside gate contact structure 51). This structure takes advantage of the gate cut area for signal transfer from the frontside to the backside.

In embodiments of the present application (See, for example, FIGS. 23A and 24), the VBPR structure (i.e., the second VBPR structure 53) is in contact with the frontside BEOL structure.

In embodiments of the present application, the dielectric layer 24 has a topmost surface that is substantially coplanar with a topmost surface of the gate structure, and a bottommost surface that lands on the backside power rail 72.

In embodiments of the present application (See, for example, FIGS. 23A and 24), the dielectric layer 24 has a topmost surface that is substantially coplanar with a topmost surface of the gate structure (i.e., second gate structure 29), and a bottommost surface that lands on the backside power rail 72.

In some embodiments of the present application (See, for example, FIG. 24), the VBPR structure (i.e., the second VBPR structure 53) directly contacts a sidewall of the semiconductor device layer 14.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a fork sheet transistor located on a frontside of a semiconductor device layer and comprising a plurality of semiconductor channel material nanosheets, a gate structure contacting each semiconductor channel material nanosheet of the plurality of semiconductor channel material nanosheets, and source/drain regions;
a backside power rail located on a backside of the semiconductor device layer;
a via-to-backside power rail (VBPR) structure in electrical contact with the backside power rail and one of the source/drain regions of the fork sheet transistor; and
a dielectric layer separating the VBPR structure from each of the gate structure, the plurality of semiconductor channel material nanosheets, the semiconductor device layer and the source/drain region that is in electrical contact with the backside power rail.

2. The semiconductor structure of claim 1, wherein an upper portion of the VBPR structure is present in a middle-of-the-line (MOL) dielectric layer, and the upper portion of the VBPR structure directly contacts the MOL dielectric layer.

3. The semiconductor structure of claim 2, wherein the upper portion of the VBPR structure that is present in the MOL dielectric layer has a shape that differs from a shape of a remaining portion of the VBPR structure.

4. The semiconductor structure of claim 1, wherein the VBPR structure includes a merged frontside source/drain contact structure in direct physically contact with a topmost surface of the source/drain region that is in electrical contact with the backside power rail.

5. The semiconductor structure of claim 1, wherein the VBPR structure extends into the backside power rail.

6. The semiconductor structure of claim 1, wherein the dielectric layer lands on a surface of the backside power rail.

7. The semiconductor structure of claim 1, further comprising a frontside back-end-of-the-line (BEOL) structure located above the transistor, wherein the frontside BEOL structure is in electrical contact with the gate structure of the transistor by a frontside gate contact structure.

8. The semiconductor structure of claim 7, wherein the VBPR structure is in contact with the frontside BEOL structure.

9. The semiconductor structure of claim 1, wherein the dielectric layer has a topmost surface that is substantially coplanar with a topmost surface of the gate structure, and a bottommost surface that lands on the backside power rail.

10. A semiconductor structure comprising:
a fork sheet transistor located on a frontside of a semiconductor device layer and comprising a plurality of semiconductor channel material nanosheets, a gate structure contacting each semiconductor channel material nanosheet of the plurality of semiconductor channel material nanosheets, and source/drain regions;
a backside power rail located on a backside of the semiconductor device layer;
a via-to-backside power rail (VBPR) structure located in a non-active device area and in electrical contact with the backside power rail and a topmost surface and a sidewall surface of one of the source/drain regions of the fork sheet transistor; and
a dielectric layer separating the VBPR structure from each of the gate structure and the plurality of semiconductor channel material nanosheets.

11. The semiconductor structure of claim 10, wherein an upper portion of the VBPR structure is present in a middle-of-the-line (MOL) dielectric layer, and the upper portion of the VBPR structure directly contacts the MOL dielectric layer.

12. The semiconductor structure of claim 11, wherein the upper portion of the VBPR structure that is present in the MOL dielectric layer has a shape that differs from a shape of a remaining portion of the VBPR structure.

13. The semiconductor structure of claim 10, wherein the VBPR structure includes a merged frontside source/drain contact structure in direct physically contact with a topmost surface of the source/drain region that is in electrical contact with the backside power rail.

14. The semiconductor structure of claim 10, wherein the VBPR structure extends into the backside power rail.

15. The semiconductor structure of claim 10, wherein the dielectric layer lands on a surface of the backside power rail.

16. The semiconductor structure of claim 10, further comprising a frontside back-end-of-the-line (BEOL) structure located above the transistor, wherein the frontside BEOL structure is in electrical contact with the gate structure of the transistor by a frontside gate contact structure.

17. The semiconductor structure of claim 16, wherein the VBPR structure is in contact with the frontside BEOL structure.

18. The semiconductor structure of claim 10, wherein the dielectric layer has a topmost surface that is substantially coplanar with a topmost surface of the gate structure, and a bottommost surface that lands on the backside power rail.

19. The semiconductor structure of claim 10, wherein the dielectric layer separates the VBPR structure from the semiconductor device layer.

20. The semiconductor structure of claim 10, wherein the VBPR structure directly contacts a sidewall of the semiconductor device layer.
